(19) United States
(12) Patent Application Publication
(10) Pub. No.: US 2025/0198854 A1
(43) Pub. Date: Jun. 19, 2025

(54) POWER MODULE AND METHOD FOR MEASURING THE TEMPERATURE OF THE POWER MODULE

(71) Applicant: Robert Bosch GmbH, Stuttgart (DE)

(72) Inventors: Manuel Riefer, Reutlingen (DE); Jonathan Winkler, Sonnenbuehl (DE); Sebastian Strache, Wannweil (DE)

(21) Appl. No.: 19/054,200

(22) Filed: Feb. 14, 2025

(30) Foreign Application Priority Data
Feb. 26, 2005 (DE) 10 2024 201 716.7

(51) Int. Cl. G01K 7/16; H03K 17/687

(52) U.S. Cl. CPC G01K 7/16; H03K 17/687

(57) ABSTRACT

A power module. The power module includes a semiconductor switch comprising a gate terminal, and a gate driver for switching the semiconductor switch, which is connected to the gate terminal, wherein the gate driver is designed to apply an oscillating voltage to the gate terminal to thereby set a phase shift between a gate current and a gate voltage to a predefined value, wherein the gate driver is designed to detect a deviation of the phase shift from the predefined value, and wherein the gate driver is designed to detect a gain factor between the gate current and the gate voltage and, based on the gain factor and the deviation of the phase shift, to ascertain a gate resistance and an input capacitance of an equivalent resonant circuit of the semiconductor switch.

### FIELD

The present invention relates to a power module. The power module in particular comprises a temperature measurement. Furthermore, the present invention relates to a method for adjusting the temperature of the power module.

### BACKGROUND INFORMATION

For monitoring the correct functioning of power semiconductors, the temperature must be monitored during operation. Temperature sensors or parasitic properties of the power semiconductor can be used for this purpose. If parasitic properties of the power semiconductor are used, the temperature can typically be measured with less delay than when using discrete sensors. Classic temperature-sensitive electrical parameters (TSEPs) of power semiconductors are the diode forward voltage of the body diode of MOSFETs, or the collector-emitter voltage of IGBTs. These methods require access to the power path of the power semiconductor and thus an accurate measurement with simultaneously high dielectric strength of the measurement input.

On the other hand, it is now possible to ascertain the temperature via temperature-sensitive elements in the gate circuit. In this case, the temperature dependence of the internal gate resistance of a power semiconductor is used. So far, this method has been used to measure the temperature of IGBTs in the off state, see, for example, M. Denk and M. Bakran, “An IGBT Driver Concept with Integrated Real-Time Junction Temperature Measurement,” PCIM Europe 2014; International Exhibition and Conference for Power Electronics, Intelligent Motion, Renewable Energy and Energy Management, 2014, pp. 1-8. The gate of the IGBT is excited with the resonance frequency, and the current into the gate is measured. The temperature can be determined from the current signal since the current flow decreases with increasing temperature due to the increased series inductance.

### SUMMARY

Advantageously, according to the present invention, a temperature measurement is carried out at the gate of a semiconductor switch, for example a silicon carbide MOSFET. According to an example embodiment of the present invention, for this purpose, a recurring signal is applied and the frequency is selected in such a way that the phase shift between the gate voltage and the gate current is at a predefined value, e.g., 45°. A change in temperature and the resulting change in the internal gate resistance now leads to a reduction in the phase shift and thus serves as a TSEP.

The present invention makes it possible to measure the current at semiconductor switches, in particular SiC MOSFETs, via the gate path during active conduction operation and allows the junction temperature to be measured under current flow or makes compensation of the temperature error caused by current flow possible. This development of the TSEP measurement via the internal gate resistance by means of phase shift allows compensation of the current-dependent temperature measurement error of the method.

This current dependence is caused by the change in the input capacitance of the semiconductor switch, in particular MOSFETS, due to the load current through the semiconductor switch. Therefore, the change in the gain factor (gain) between the gate current and the gate voltage is taken into account. From the gain and phase data, the capacitance and resistance of the RLC resonant circuit can now be determined if the inductance is known. This compensated measurement can be realized by a phase-gain detector, which can be integrated into an ASIC with little area requirements. As a result, both the current distribution and the temperature distribution of a power module can be ascertained, allowing the symmetry to be determined and influenced.

The power module comprises a semiconductor switch with a gate terminal and a gate driver. The gate driver is connected to the gate terminal for switching the semiconductor switch. The gate driver is also designed to determine the temperature on the basis of measurements in the gate circuit.

According to an example embodiment of the present invention, the gate driver is designed to apply an oscillating voltage to the gate terminal. As a result, a phase shift occurs between a gate current and a gate voltage, wherein the frequency of the oscillating voltage is selected such that the phase shift is set to a predefined value.

According to an example embodiment of the present invention, the gate driver is further designed to detect a deviation of the phase shift from the predefined value. Additionally, the gate driver is designed to detect a gain factor between the gate current and the gate voltage and, based on the gain factor and the deviation of the phase shift, to ascertain a gate resistance and an input capacitance of an equivalent resonant circuit of the semiconductor switch.

A semiconductor switch, in particular a SiC MOSFET, can alternatively be viewed as an RLC series resonant circuit with an electrical gate resistance, a gate inductance, and an input capacitance. In particular, the gate resistance inter alia consists of polysilicon. It is provided that the gate resistance is temperature-dependent, as a result of which the damping of the series resonant circuit changes with temperature fluctuations. As the temperature increases, the gate resistance and thus the damping increases.

The resonant circuit can now be operated in resonance, which means that the impedance of inductance and capacitance cancel each other out. As a result, the resistance for the excitation signal only corresponds to the real part and thus to the internal gate resistance. According to the present invention, the gate driver is designed not to operate the resonant circuit at resonance, but rather, particularly advantageously, at a frequency at which the real part of the impedance corresponds to the imaginary part. At this operating point, a phase shift of +45° or −45° occurs between the gate voltage and the gate current.

By increasing the temperature, the gate resistance now increases again, and the phase shift thus decreases. By evaluating the phase shift, the temperature can be determined. However, since the input capacitance is also current-dependent, a measurement error occurs when measuring the temperature under current flow due to a detuning of the gate resonant circuit. The input capacitance is increased by the Miller effect. The gate-drain capacitance is increased by the gain factor.

The temperature and the current can be ascertained from the two values of gain factor and phase shift between the gate voltage and the gate current. For this purpose, the complex resistance of the circuit is ascertained particularly advantageously from the phase signal and the gain signal.

Preferred developments of the present invention are disclosed herein.

According to an example embodiment of the present invention, preferably, the gate driver is designed to ascertain a temperature of the semiconductor switch from the gate resistance. Alternatively or additionally, the gate driver is designed to ascertain a load current of the semiconductor switch from the input capacitance. Preferably, a current dependence of the input capacitance and a temperature dependence of the gate resistance are known so that both values of temperature and load current can thus be ascertained. Via the current dependence of the input capacitance due to the Miller effect, the load current can be preferably determined via the gain characteristic of the semiconductor switch.

In an advantageous embodiment of the present invention, the gate driver is designed to adjust a frequency of the oscillating voltage if the phase shift deviates from the predefined value. In this way, said deviation of the phase shift can be minimized. The gate driver is further designed to ascertain the gate resistance and the input capacitance of the equivalent resonant circuit of the semiconductor switch based on the gain factor and the frequency of the oscillating voltage. In this way, a phase-locked loop is formed in particular, which exhibits high sensitivity since the phase angle is set to a value that accurately represents both the real and imaginary parts of the impedance of the gate circuit.

According to an example embodiment of the present invention, the gate driver is advantageously an application-specific integrated circuit. Particularly advantageously, the gate driver and the semiconductor switch are integrally designed. In this way, gate paths can be kept particularly short, as a result of which the gate connection has a low influence on the temperature measurement.

The semiconductor switch is preferably a MOSFET. The semiconductor switch is particularly preferably a silicon carbide MOSFET, SiC-MOSFET.

The present invention also relates to a method for measuring the temperature of a power module. The power module comprises a semiconductor switch with a gate terminal and a gate driver. The gate driver is connected to the gate terminal for switching the semiconductor switch. The gate driver is also designed to determine the temperature on the basis of measurements in the gate circuit.

According to an example embodiment of the present invention, for carrying out the method, an oscillating voltage is initially applied to the gate terminal. As a result, a phase shift occurs between a gate current and a gate voltage, wherein the frequency of the oscillating voltage is selected such that the phase shift is set to a predefined value.

In addition, a deviation of the phase shift from the predefined value is detected. Additionally, a gain factor between the gate current and the gate voltage is detected and, based on the gain factor and the deviation of the phase shift, a gate resistance and an input capacitance of an equivalent resonant circuit of the semiconductor switch are ascertained. This has the same advantages as those already described above.

According to an example embodiment of the present invention, preferably, a temperature of the semiconductor switch is ascertained from the gate resistance. Alternatively or additionally, a load current of the semiconductor switch is ascertained from the input capacitance. Preferably, a current dependence of the input capacitance and a temperature dependence of the gate resistance are known so that both values of temperature and load current can thus be ascertained. Via the current dependence of the input capacitance due to the Miller effect, the load current can be preferably determined via the gain characteristic of the semiconductor switch.

In an advantageous embodiment of the present invention, if the phase shift deviates from the predefined value, a frequency of the oscillating voltage is also adjusted. In this way, said deviation of the phase shift can be minimized. Based on the gain factor and the frequency of the oscillating voltage, the gate resistance and the input capacitance of the equivalent resonant circuit of the semiconductor switch are ascertained. In this way, a phase-locked loop is formed in particular, which exhibits high sensitivity since the phase angle is set to a value that accurately represents both the real and imaginary parts of the impedance of the gate circuit.

### BRIEF DESCRIPTION OF THE DRAWINGS

In the following, exemplary embodiments of the present invention are described in detail with reference to the figures.

FIG. 1 is a schematic representation of a power module according to an exemplary embodiment of the present invention.

FIG. 2 is a schematic flow chart of a current determination of a load current of the power module according to the exemplary embodiment of the present invention.

FIG. 3 is a schematic flow chart of a temperature determination of the power module according to the exemplary embodiment of the present invention.

FIG. 4 is a schematic flow chart for ascertaining a gate resistance and an input capacitance of the power module according to the exemplary embodiment of the present invention by means of a phase-locked loop.

### DETAILED DESCRIPTION OF EXAMPLE EMBODIMENTS

Preferably, the same components, elements and/or units in all figures are provided with the same reference signs.

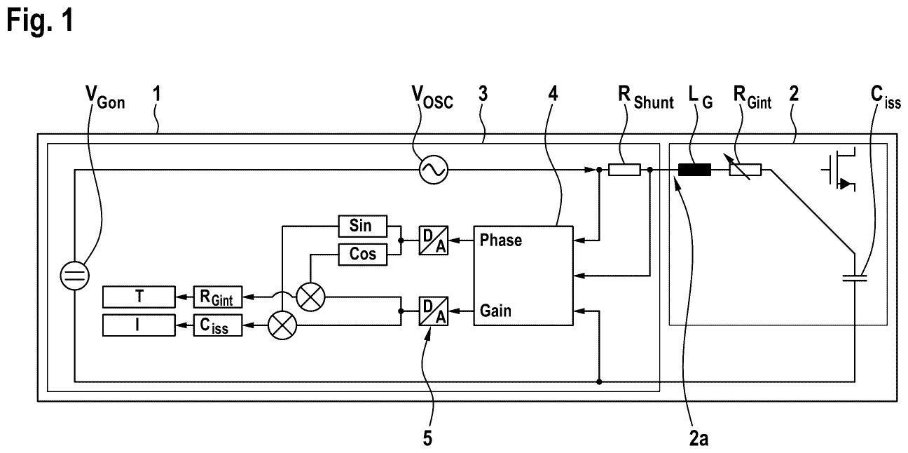

FIG. 1 schematically shows a power module 1 according to an exemplary embodiment of the present invention. The power module 1 comprises a semiconductor switch 2 with a gate terminal 2a. The semiconductor switch 2 is a silicon carbide MOSFET and is alternatively represented in FIG. 1 by an RLC series resonant circuit with the gate resistance R_{Gint}, the gate inductance L_{G}, and the input capacitance Cᵢₛₛ. The gate resistance R_{Gint} comprises polysilicon and is temperature-dependent. The input capacitance Cᵢₛₛ is current-dependent.

The power module 1 also comprises a gate driver 3 for switching the semiconductor switch 2, wherein the gate driver 3 is connected to the gate terminal 2. The gate driver 3 is an application-specific integrated circuit ASIC, wherein the gate driver 3 and the semiconductor switch 2 are integrally designed. This implementation is particularly advantageous since the gate paths can be kept as short as possible. As a result, the gate connection has a low influence on the measurement. In addition, this combination makes possible a secure coupling of the parameters of the semiconductor switch 2 with the gate driver 3.

The gate driver 3 is designed to apply an oscillating voltage VOSC with such a frequency to the gate terminal 2a that the real part of the impedance corresponds to the imaginary part. At this operating point, a phase shift of +45° or −45° occurs between the gate voltage and the gate current.

As a result of the current dependence of the input capacitance Cᵢₛₛ on a load current I through the semiconductor switch 2, a measurement error occurs during temperature measurement under current flow due to a detuning of the gate resonant circuit. The input capacitance Cᵢₛₛ is increased by the Miller effect. The gate-drain capacitance Cᵣₛₛ is increased by the gain factor, also referred to as gain.

Both the temperature T and the load current I can be ascertained from the two values of gain factor or gain and phase shift between the gate voltage and the gate current. The gate driver 3 is designed to determine the input capacitance Cᵢₛₛ and the gate resistance R_{Gint} by means of a phase-gain detector 4 and a D/A converter 5. For this purpose, the complex resistance of the circuit is ascertained from the phase signal and the gain signal. If the current dependence of the input capacitance Cᵢₛₛ and the temperature dependence of the gate resistance R_{Gint} are known, both values T and I can thus be ascertained. Via the current dependence of the input capacitance due to the Miller effect, the load current I can be determined via the gain characteristic of the semiconductor switch 2. The following formulas are provided for this conversion into real and imaginary parts:

$$Re \{ Z \} = Z * cos ( α ) ; Im \{ Z \} = Z * sin ( α )$$

The gain factor Gain is composed as follows:

$$Gain = \frac{{V}_{S hunt}}{{V}_{G S}} = \frac{{I}_{G} * {R}_{G}}{{V}_{G S}}$$

The current flow is limited by the impedance Z; in this context, X_{L} represents the reactance of the inductances and X_{C} represents the reactance of the capacitances of the semiconductor switch 2.

$$Z = \sqrt{( {( {X}_{L} + {X}_{C} )}^{2} + {( {R}_{G ( Int )} + {R}_{G} )}^{2} )}$$

Thus, the following applies to the gain current I_{G}, where V_{GS} is the gate-source voltage of the semiconductor switch 2:

$${I}_{G} = \frac{{V}_{G S}}{Z}$$

By substitution, the following applies to the gain:

$$Gain = \frac{{I}_{G} * {R}_{G}}{{V}_{G S}} = \frac{\frac{{V}_{G S}}{Z} * {R}_{G}}{G S} = \frac{R}{Z}$$

Rearranging results in:

$$Z = \frac{{R}_{ext}}{Gain}$$

Since the phase shift φ is also measured, the measured impedance Z can now be broken down into resistance R and reactance X:

$$cos ( φ ) = \frac{R}{Z} = \frac{{R}_{Gint} + {R}_{ext}}{Z} \text{==>} Z = \frac{{R}_{Gint} + {R}_{ext}}{cos ( φ )}$$

Equating results in:

$$\frac{{R}_{ext}}{Gain} = \frac{{R}_{Gint} + {R}_{ext}}{cos ( φ )} \text{==>} {R}_{Gint} = \frac{{R}_{ext}}{Gain} * cos ( φ ) - {R}_{ext}$$

For the reactance X along with the individual reactances of inductances X_{L} and capacitances X_{C} of the semiconductor switch 2, the following applies:

$$sin ( φ ) = \frac{X}{Z} = \frac{{X}_{L} + {X}_{C}}{Z} \text{==>} Z = \frac{{X}_{L} + {X}_{C}}{sin ( φ )}$$

Equating here results in:

$$\frac{{R}_{ext}}{Gain} = \frac{{X}_{L} + {X}_{C}}{sin ( φ )} \text{==>} {X}_{C} = \frac{{R}_{ext}}{Gain} * sin ( φ ) - {X}_{L}$$

For the previous formula, the following applies:

$${X}_{L} = 2 π * {F}_{o s c} * {L}_{G} ; {X}_{C} = - \frac{1}{2 π * {F}_{o s c} * {C}_{i s s}}$$

Since the total resistance R_{Ext} due to the placement and the gate inductance L_{G} due to the design of the gate path are constant and known for a design, and the frequency F_{OSC} of the oscillating voltage V_{OSC} is also known, Cᵢₛₛ and R_{Gint} can be determined in this way.

Thus, the temperature T can be determined via the change in the gate resistance R_{Gint}. Cᵢₛₛ exhibits a temperature dependence and a current dependence: Due to the Miller effect, the Miller capacitance of the semiconductor switch 2, which is calculated from the feedback capacitance Cᵣₛₛ and the gate-drain capacitance C_{GD} as Cᵣₛₛ/C_{GD}, is increased by the gain factor Gain:

$${C}_{M i l l e r} = \vert Gain \vert * {C}_{r s s}$$

In the ohmic region of the semiconductor switch 2, the gain factor increases approximately linearly with the current (ΔV_{ds}=I_{d}*Δr_{ds}). However, as the temperature T rises, the gain factor Gain inter alia decreases due to the decreasing charge carrier mobility and the lower proportion of the channel resistance in the total resistance of the semiconductor switch 2 with increasing temperature T. An influencing factor of the temperature T on the gain factor is described in Li, Yaoye: “Analysis of basic performance parameters and temperature e_ect of SiC-MOSFET,” in: Journal of Physics: Conference Series 2435 (2023), February, no. 1, 012020. dx.doi.org/10.1088/1742-6596/2435/1/012020.-DOI 10.1088/1742-6596/2435/1/012020.-ISSN1742-6588, 1742-6596.

The single-chip temperature measurement can be accomplished for each power module 1 with individually routed gate terminals 2a. In the case of a sum gate, the measurement of an average temperature of the semiconductor switches 2 is possible. In this measurement, an averaging of the individual gate resistances R_{Gint} takes place. This is in contrast to measuring the temperature via the body diode, with which the hottest semiconductor switch 2 determines the voltage drop across the parallel semiconductor switches 2 since it conducts first.

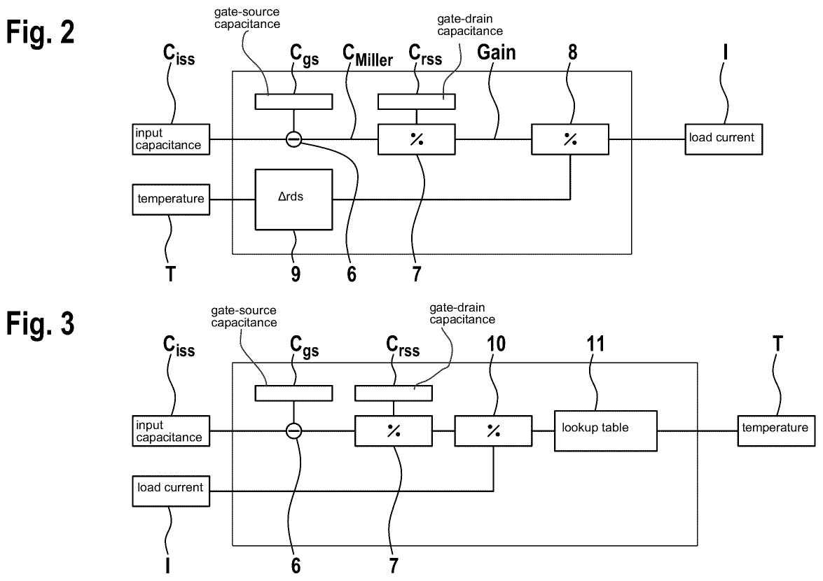

FIG. 2 schematically shows a flow chart of a current determination of the load current I of the power module 1 according to the exemplary embodiment of the present invention. Determining the gate resistance R_{Gint} makes temperature determination possible. With a known temperature T and a known temperature dependence of the gain Gain of the semiconductor switch 2, the gain factor Gain can now be determined from the change in the input capacitance Cᵢₛₛ. For this purpose, the Miller capacitance C_{Miller} is determined from the input capacitance Cᵢₛₛ and the gate-source capacitance C_{GS} by subtraction 6, and the gain factor Gain is determined from the Miller capacitance C_{Miller} and the feedback capacitance Cᵣₛₛ by a first division 7. With the aid of the gain factor Gain, a conclusion about the load current I can now be drawn via the temperature dependence of the gain. This is effected by a second division 8 of the gain factor Gain by Δr_{ds} (9), where Δr_{ds} can be ascertained from the temperature T, as explained in the aforementioned source. In particular, the following applies:

$${r}_{d s} = \frac{1}{{μ}_{n} {C}_{O X} \frac{W}{L} ( {V}_{G S} - {V}_{T h} )}$$

W is the channel width, C_{OX} is the capacitance of the gate oxide layer, μₙ is the charge carrier mobility, L is the channel length, V_{GS} is the gate-source voltage, V_{TH} is the threshold voltage.

FIG. 3 schematically shows a flow chart of a temperature determination of the power module 1 according to the exemplary embodiment of the present invention. In the event that the load current I is known, the dependence can also be used in reverse in comparison to the variant described above with reference to FIG. 2, by determining the temperature T based on the load current I and the input capacitance Cᵢₛₛ. As a result, the accuracy of the temperature measurement can be improved, and a compensation factor can also be introduced. This current can be ascertained, for example, by a current sensor. Another possibility would be to use the target current of the inverter control.

For this purpose, the Miller capacitance C_{Miller} is determined from the input capacitance Cᵢₛₛ and the gate-source capacitance Cas by subtraction 6, and the gain factor Gain is determined from the Miller capacitance C_{Miller} and the feedback capacitance Cᵣₛₛ by a first division 7. With the aid of the gain factor Gain and the load current I, the value for Δr_{ds} is ascertained by means of a third division 10. As described above, Δr_{ds} depends on the temperature T. Thus, for example, the temperature can be ascertained from Δr_{ds} by means of a lookup table 11.

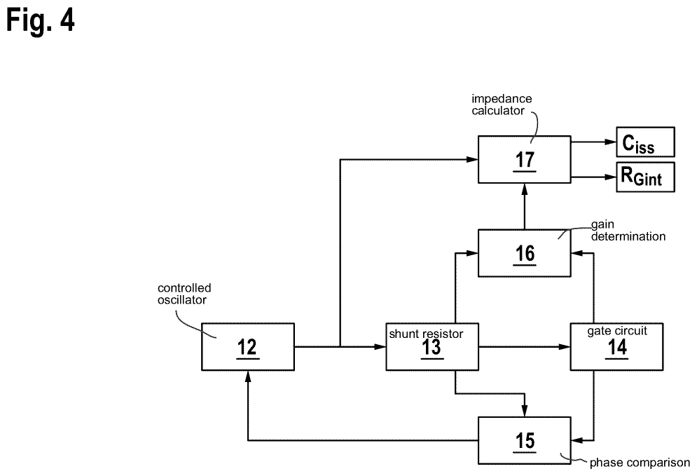

FIG. 4 schematically shows a flow chart for ascertaining a gate resistance R_{Gint} and an input capacitance Cᵢₛₛ of the power module 1 according to the exemplary embodiment of the present invention by means of a phase-locked loop. Here, the measurement frequency is continuously adjusted in order to achieve a constant phase shift. For evaluating the temperature T and the load current I, the gain, i.e., a value proportional to the impedance, is recorded in this case. Additionally, the frequency must be included in the evaluation. Based on the gain and the phase position, the resistive and capacitive components of the measurement can be determined directly. Based on the frequency, the capacitance can also be calculated from the reactance.

A controlled oscillator 12 generating the oscillating voltage VOSC outputs the oscillating voltage VOSC to the gate circuit 14 via a shunt resistor 13, wherein the frequency F_{OSC} of the controlled oscillator 12 is adjusted by means of a phase comparison 15. The gate resistance R_{Gint} and the input capacitance Cᵢₛₛ are determined by means of a gain determination 16 and an impedance calculator 17.

For a design of the phase-locked loop for a constant phase shift φ of 45°, the calculation of Cᵢₛₛ and R_{Gint} is as follows:

F_{OSC} is established via:

$${X}_{L} ( {F}_{O S C} ) + {X}_{C} ( {F}_{OSC} ) = {R}_{Gint}$$

For R_{Gint} in this case, the following applies:

$${R}_{Gint} = \frac{{R}_{ext}}{Gain} * cos ( 45 ° ) - {R}_{ext} = \frac{{R}_{ext}}{Gain} * \frac{\sqrt{2}}{2} - {R}_{ext}$$

For Cᵢₛₛ with known L_{G} in this case, the following applies:

$$X = {X}_{L} + {X}_{C} = - \frac{1}{2 π * {F}_{o s c} * {C}_{i s s}} + 2 π * {F}_{o s c} * {L}_{G} = \frac{{R}_{ext}}{Gain} * sin ( 45 ° ) - {R}_{ext} = \frac{{R}_{ext}}{Gain} * \frac{\sqrt{2}}{2} - {R}_{ext} - \frac{1}{2 π * {F}_{o s c} * {C}_{i s s}} + 2 π * {F}_{o s c} * {L}_{G} = \frac{{R}_{ext}}{Gain} * \frac{\sqrt{2}}{2} - {R}_{ext} - \frac{1}{2 π * {F}_{o s c} * {C}_{i s s}} = \frac{{R}_{ext}}{Gain} * \frac{\sqrt{2}}{2} - {R}_{ext} - 2 π * {F}_{osc} * {L}_{G} - 1 = ( \frac{{R}_{ext}}{Gain} * \frac{\sqrt{2}}{2} - {R}_{ext} - 2 π * {F}_{o s c} * {L}_{G} ) * 2 π * {F}_{o s c} * {C}_{i s s} - \frac{1}{( \frac{{R}_{ext}}{Gain} * \frac{\sqrt{2}}{2} - {R}_{ext} - 2 π * {F}_{o s c} * {L}_{G} ) * 2 π * {F}_{o s c}} = {C}_{i s s}$$

Thus, by means of gain measurement and frequency measurement at a known, set phase shift φ between the gate current and the gate voltage, the input capacitance and the gate resistance can be determined and, as explained with reference to FIGS. 2 and 3, can once again be used for evaluating current and temperature.

The advantages of this method are the high sensitivity of the measurement since the phase angle can be set to a value that accurately represents both the real and imaginary parts.

1-8. (canceled)

9. A power module, comprising:
a semiconductor switch including a gate terminal; and
a gate driver connected to the gate terminal and configured to switch the semiconductor switch,
wherein the gate driver is configured to apply an oscillating voltage to the gate terminal to thereby set a phase shift between a gate current and a gate voltage to a predefined value,
wherein the gate driver is configured to detect a deviation of the phase shift from the predefined value, and
wherein the gate driver is configured to detect a gain factor between the gate current and the gate voltage and, based on the gain factor and the deviation of the phase shift, to ascertain a gate resistance and an input capacitance of an equivalent resonant circuit of the semiconductor switch.

10. The power module according to claim 9, wherein the predefined value is +45° or −45°.

11. The power module according to claim 9, wherein the gate driver is configured to: (i) ascertain a temperature of the semiconductor switch from the gate resistance and/or (ii) ascertain a load current of the semiconductor switch from the input capacitance.

12. The power module according to claim 9, wherein, when the phase shift deviates from the predefined value, the gate driver is configured to adjust a frequency of the oscillating voltage to minimize the deviation, wherein the gate driver is further configured to ascertain the gate resistance and the input capacitance of the equivalent resonant circuit of the semiconductor switch based on the gain factor and the frequency of the oscillating voltage.

13. The power module according to claim 9, wherein the gate driver is an application-specific integrated circuit and the gate driver and the semiconductor switch are configured integrally.

14. The power module according to claim 9, wherein the semiconductor switch is a SiC-MOSFET.

15. A method for measuring a temperature of a power module, wherein the power module includes a semiconductor switch with a gate terminal, and a gate driver connected to the gate terminal configured to switch the semiconductor switch, the method comprising the following steps:
applying an oscillating voltage to the gate terminal to thereby set a phase shift between a gate current and a gate voltage to a predefined value;
detecting a deviation of the phase shift from the predefined value; and
detecting a gain factor between the gate current and the gate voltage and ascertaining a gate resistance and an input capacitance of an equivalent resonant circuit of the semiconductor switch based on the gain factor and the deviation of the phase shift.

16. The method according to claim 15, wherein a temperature of the semiconductor switch is ascertained from the gate resistance and/or a load current of the semiconductor switch is ascertained from the input capacitance.

17. The power module according to claim 15, wherein, when the phase shift deviates from the predefined value, a frequency of the oscillating voltage is adjusted to minimize the deviation, wherein the gate resistance and the input capacitance of the equivalent resonant circuit of the semiconductor switch are ascertained based on the gain factor and the frequency of the oscillating voltage.
